(19) United States
(12) Patent Application Publication
(10) Pub. No.: US 2024/0412776 A1
(43) Pub. Date: Dec. 12, 2024

(54) MEMORY DEVICE INCLUDING A PAGE BUFFER

(71) Applicant: SK hynix Inc., Gyeonggi-do (KR)

(72) Inventors: Jong Seok JUNG, Gyeonggi-do (KR); Chan Keun KWON, Gyeonggi-do (KR); Kyeong Hwan PARK, Gyeonggi-do (KR); Suk Hwan CHOI, Gyeonggi-do (KR)

(21) Appl. No.: 18/483,525

(22) Filed: Oct. 10, 2023

(30) Foreign Application Priority Data
Jun. 7, 2023 (KR) 10-2023-0072765

(51) Int. Cl. G11C 11/4093; G11C 11/4074; G11C 11/4096

(52) U.S. Cl. CPC G11C 11/4093; G11C 11/4074; G11C 11/4096

(57) ABSTRACT

A memory device includes a cell string comprising a plurality of memory cells and a page buffer coupled to the cell string. The page buffer includes a latch with cross-coupled transistors. Data transferred from the cell string to the page buffer is input to gates of plural transistors included in the page buffer.

### CROSS-REFERENCE TO RELATED APPLICATIONS

This patent application claims the benefit of Korean Patent Application No. 10-2023-0072765, filed on Jun. 7, 2023, the entire disclosure of which is incorporated herein by reference.

### TECHNICAL FIELD

One or more embodiments of the present disclosure described herein relate to a memory device, and more particularly, to a page buffer included in the memory device.

### BACKGROUND

A data processing system includes a memory system or a data storage device. The data processing system can be developed to store more voluminous data in the data storage device, store data in the data storage device faster, and read data stored in the data storage device faster. The memory system or the data storage device can include non-volatile memory cells and/or volatile memory cells for storing data.

### BRIEF DESCRIPTION OF THE DRAWINGS

The description herein makes reference to the accompanying drawings wherein like reference numerals refer to like parts throughout the figures.

FIG. 1 illustrates a memory device according to an embodiment of the present disclosure.

FIG. 2 illustrates a page buffer included in the memory device according to an embodiment of the present disclosure.

FIG. 3 illustrates a first example of the page buffer according to an embodiment of the present disclosure.

FIG. 4 illustrates an operation of the page buffer according to an embodiment of the present disclosure.

FIG. 5 illustrates a second example of the page buffer according to an embodiment of the present disclosure.

FIG. 6 illustrates operational comparison between the page buffers shown in FIGS. 3 and 5.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language include hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory (ies) that work together to cause an apparatus, such as a mobile phone or server, to perform various functions) and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

Embodiments described herein provide a memory device including a page buffer which is capable of reducing current consumption.

An embodiment of the present disclosure may provide a page buffer, included in a memory device, which is insensitive to fluctuations in an internal voltage in the memory device and could more easily identify or recognize data output from non-volatile memory cells.

In addition, an embodiment of the present disclosure can provide a page buffer including at least one transistor designed to have a shorter channel than a conventional one because a transistor constituting the page buffer in the memory device does not need to have a long channel, thereby reducing a size of the page buffer and increasing an integration degree of the memory device.

In an embodiment, a memory device can include a cell string comprising a plurality of memory cells; and a page buffer coupled to the cell string, the page buffer comprising a latch with cross-coupled transistors. Data transferred from the cell string to the page buffer can be input to gates of plural transistors included in the page buffer.

The plural transistors can include a first node of the cross-coupled transistors; a first PMOS transistor coupled to a power voltage node; and a first NMOS transistor coupled to the first node.

The cross-coupled transistors can include a second NMOS transistor having a gate coupled to the first node; and a third NMOS transistor having a gate coupled to a second node temporarily storing a second value which is inverted from a first value temporarily stored in the first node.

The first NMOS transistor can be arranged between the first node and the third NMOS transistor.

The page buffer can further include a third PMOS transistor arranged between the first node and the first PMOS transistor. An inverted signal of a sense set signal can be input to a gate of the third PMOS transistor.

The page buffer can further include a second PMOS transistor coupled to a power voltage node and a fourth NMOS transistor coupled to a ground voltage node. An inverted signal of a sense reset signal can be input to gates of the second PMOS transistor and the fourth NMOS transistor.

The page buffer can include the first node having a logical high level during a precharge section. The first node can be configured to have the logical high level when data is transferred from the cell string and make a transition from the logical high level to a logical low level when no data is transferred from the cell string.

Each of the memory cells can be configured to store multi-bit data. The data transferred from the cell string can include 1-bit data which is recognized by a read voltage among the multi-bit data when the read voltage is applied to at least one of the memory cells.

In another embodiment, a memory device can include a cell string comprising plural memory cells; a page buffer coupled to the cell string, the page buffer comprising a latch with cross-coupled transistors; voltage generation circuitry configured to generate a read voltage and a pass voltage; and control circuitry configured to generate a control signal to be input to the page buffer and the voltage generation circuitry.

Data transferred from the cell string to the page buffer can be input to gates of plural transistors included in the page buffer.

The plural transistors can include a first node of the cross-coupled transistors; a first PMOS transistor coupled to a power voltage; and a first NMOS transistor coupled to the first node.

The cross-coupled transistors can include a second NMOS transistor having a gate coupled to the first node; and a third NMOS transistor having a gate coupled to a second node temporarily storing a second value which is inverted from a first value temporarily stored in the first node.

The first NMOS transistor can be arranged between the first node and the third NMOS transistor.

The page buffer can further include a third PMOS transistor arranged between the first node and the first PMOS transistor. An inverted signal of a sense set signal can be input to a gate of the third PMOS transistor.

The page buffer can further include a second PMOS transistor coupled to a power voltage node and a fourth NMOS transistor coupled to a ground voltage node. An inverted signal of a sense reset signal can be input to gates of the second PMOS transistor and the fourth NMOS transistor.

The page buffer can include the first node having a logical high level during a precharge section. The first node can be configured to have the logical high level when data is transferred from the cell string and make a transition from the logical high level to a logical low level when no data is transferred from the cell string.

Each of the memory cells can be configured to store a multi-bit data. The data transferred from the cell string can include 1-bit data which is recognized by a read voltage among the multi-bit data when the read voltage is applied to at least one of the memory cells.

The page buffer and at least one another page buffer are coupled to the cell string. The number of page buffer coupled to the cell string can be equal to, or greater than, the number of bits of data stored in each memory cell.

The cell string and the page buffer can be coupled to each other through a bit line and a sensing output node. The memory device can further include precharge circuitry configured to precharge the bit line and the sensing output node; and at least one switch configured to control connection between the bit line and the sensing output node.

The at least one switch can be controlled by a signal output from the control circuitry.

Embodiments will now be described with reference to the accompanying drawings, wherein like numbers reference like elements.

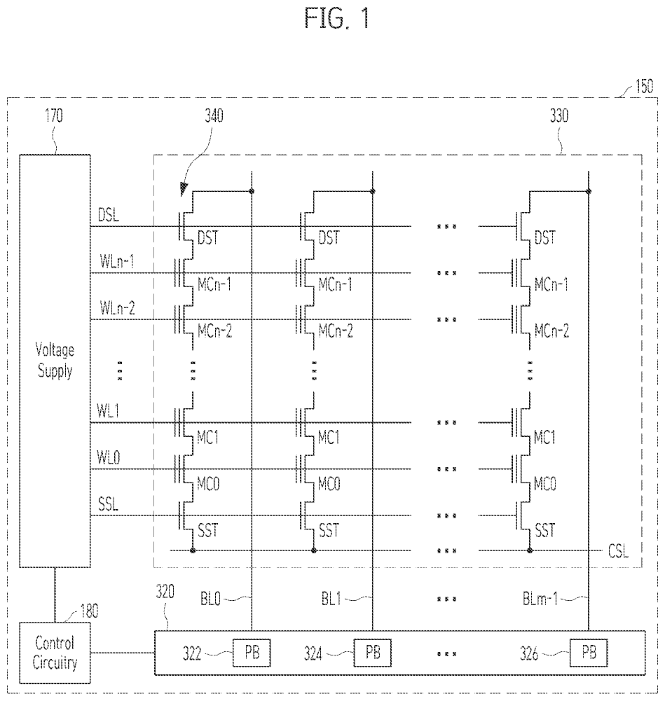

FIG. 1 illustrates a memory device 150 that includes a memory cell array circuit formed in a memory die according to an embodiment of the present disclosure.

Referring to FIG. 1, the memory device 150 may include at least one memory group 330 having a plurality of cell strings 340. Each cell string 340 may include a plurality of non-volatile memory cells MC0 to MCn−1 connected to a respective bit line of a plurality of bit lines BL0 to BLm−1. The cell strings 340 are disposed in respective columns of the memory group 330, and each cell string 340 can include at least one drain select transistor DST and at least one source select transistor SST. The non-volatile memory cells MC0 to MCn−1 of each cell string 340 may be connected in series between a drain select transistor DST and a source select transistor SST. Each of the non-volatile memory cells MC0 to MCn−1 may be configured as a multi-level cell (MLC) that stores a data item having plural bits per cell. The cell strings 340 may be electrically connected to corresponding bit lines of the bit lines BL0 to BLm−1.

In an embodiment, the memory group 330 may include NAND-type flash memory cells MC0 to MCn−1. In another embodiment, the memory group 330 can be implemented as a NOR-type flash memory, a hybrid flash memory in which at least two different types of memory cells are mixed or combined, or a one-chip NAND flash memory in which a controller is embedded in a single memory chip. In an embodiment, the memory group 330 can include a flash memory cell including a charge trap flash (CTF) layer that includes a conductive floating gate or insulating layer.

According to an embodiment, the memory device 150 shown in FIG. 1 can include at least one memory block. The memory group 330 can have a two-dimensional (2D) or three-dimensional (3D) structure. For example, each of the memory blocks in the memory device 150 may be implemented as a 3D structure, for example, a vertical structure. Each of the memory blocks may have a three-dimensional structure extending along first to third directions, for example, an x-axis direction, a y-axis direction, and a z-axis direction.

The memory group 330 including at least one memory block can be coupled to a plurality of bit lines BL, a plurality of string select lines SSL, a plurality of drain select lines DSL, a plurality of word lines WL, a plurality of dummy word lines DWL, and a plurality of common source lines CSL. In one embodiment, the memory group 330 can include a plurality of NAND strings NS which, for example, may respectively correspond to cell strings 340. Each NAND string NS may include a plurality of memory cells MC and may be connected to a respective bit line of the bit lines BL. In addition, the string select transistor SST of each NAND string NS may be connected to a common source line CSL, and the drain select transistor DST of each NAND string NS can be connected to a corresponding bit line BL. In each NAND string NS, the memory cells MC may be arranged between the string select transistor SST and the drain select transistor DST.

The memory device 150 may include a voltage supply circuit 170 which can supply a word line voltage e.g., one or more predetermined voltages such as a program voltage, a read voltage, and a pass voltage, for respective word lines of the word lines according to an operation mode, or may supply a voltage to a bulk, e.g., a well region, in which each memory block including the memory cells MC are formed. In this case, a voltage generating operation of the voltage supply circuit 170 may be performed under a control of a control circuitry 180. Also, the voltage supply circuit 170 may generate a plurality of variable read voltages to distinguish a plurality of data items from each other.

In response to the control of the control circuitry 180, one of the memory blocks (or sectors) of the memory cell array may be selected, and one of the word lines of the selected memory block may be selected. Word line voltages may be supplied to the selected word line and the unselected word line of the memory group 330, individually. The voltage supply circuit 170 may include a voltage generation circuit for generating target voltages having various levels, which are applicable to word lines of the memory group 330.

The memory device 150 may also include a read/write circuit 320 controlled by the control circuitry 180. The read/write circuit 320 may operate as a sense amplifier or a write driver according to an operation mode. For example, in a verify operation and a read operation, the read/write circuit 320 may operate as a sense amplifier for reading the data item from the memory cell array. In a program operation, the read/write circuit 320 may operate as a write driver that controls potentials of bit lines according to a data item to be stored in the memory cell array. The read/write circuit 320 may receive the data item to be programmed to the cell array from page buffers during the program operation. The read/write circuit 320 can drive bit lines based on the input data item. To this end, the read/write circuit 320 may include a plurality of page buffers (PB) 322, 324, 326, with each page buffer corresponding to each column or each bit line, or each column pair or each bit line pair. According to an embodiment, a plurality of latches may be included in each of the page buffers 322, 324, 326. According to an embodiment, the number of latches or page buffers coupled to each bit line can be equal to, or greater than, the number of bits of data stored in the memory cells MC.

The page buffers 322, 324, 326 may be coupled to a data input/output device, e.g., a serialization circuit or a serializer, through a plurality of buses BUS. When each of the page buffers 322, 324, 326 is coupled to the data input/output device through different buses, a delay that may occur in data transmission from the page buffers 322, 324, 326 can be reduced. For example, each page buffer 322, 324, 326 can perform the data transmission without a waiting time.

According to an embodiment, the memory device 150 may receive a write command, write data, and information, e.g., a physical address, regarding a location in which the write data is to be stored. The control circuitry 180 causes the voltage supply circuit 170 to generate a program pulse, a pass voltage, etc., used for a program operation performed in response to a write command, and to generate one or more voltages used for a verification operation performed after the program operation.

When a multi-bit data item is programmed in non-volatile memory cells included in the memory group 330, the error rate might be higher than that when a single-bit data item is stored in the non-volatile memory cells. For example, an error in the non-volatile memory cells may be induced due to cell-to-cell interference (CCI). In order to reduce error in the non-volatile memory cells, a width (deviation) of a threshold voltage distribution, corresponding to stored data items between the non-volatile memory cells, should be reduced.

To this end, the memory device 150 can perform an incremental step pulse programming (ISPP) operation to effectively make a narrow threshold voltage distribution of the non-volatile memory cells. In an embodiment, the memory device 150 can use the ISPP operation for multi-step program operations. For example, the memory device 150 may divide a program operation into a Least Significant Bit (LSB) program operation and a Most Significant Bit (MSB) operation according to a predetermined order between the non-volatile memory cells or pages.

A multi-bit value programmed in a memory cell in a NAND flash memory (e.g., NAND-type flash memory cells MC0 to MCn−1 in the memory group 330) can be determined based on a threshold voltage window or a threshold voltage distribution to which the cell's threshold voltage belongs. As a size of each memory cell shrinks and more bits (e.g., 3-bit, 4-bit, or 5-bit) of data are programmed per memory cell, a width of the threshold voltage window used to represent each multi-bit value becomes narrower, increasing an error rate when determining the multi-bit value stored in the memory cell. This is because process variations become more widespread when an amount of charge stored in each memory cell decreases with a feature size, resulting in large differences in threshold voltages of different memory cells storing the same value. As a result, it becomes increasingly difficult to determine to which value a threshold voltage of a memory cell corresponds.

According to an embodiment, the control circuitry 180 may include a read retry table (RRT). The RRT may be stored in the memory device 150. A read error may occur in a process of applying a read voltage to a non-volatile memory cell in the memory device 150 through a word line and reading data stored in the non-volatile memory cell. The control circuitry 180 in the memory device 150 may manage information regarding a read retry mechanism for resolving read errors. One of the information regarding the read retry mechanism is the read RRT. The read retry mechanism uses the RRT for a recorded location where the error has occurred, so that the memory device 150 can ensure data integrity by applying an appropriate correction value (e.g., changing a read voltage level) when re-reading.

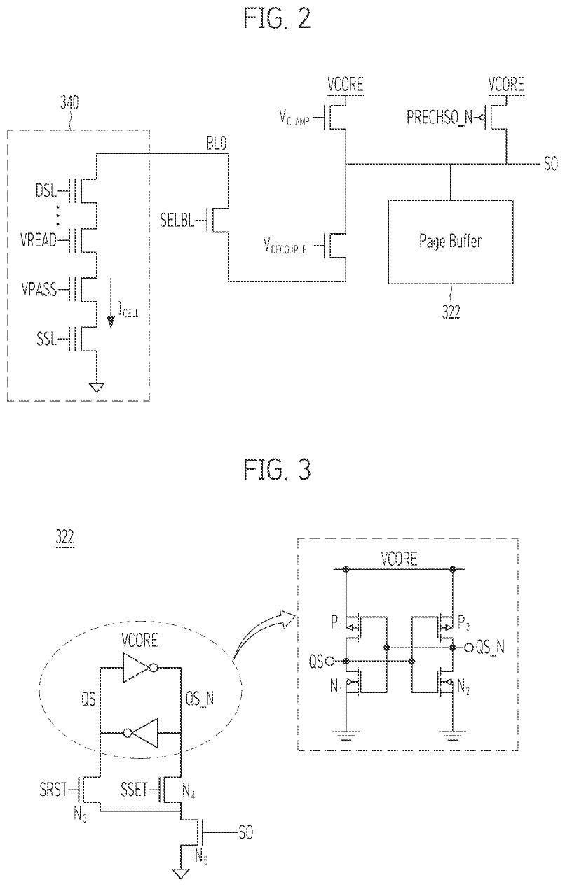

FIG. 2 illustrates a page buffer included in the memory device according to an embodiment of the present disclosure.

Referring to FIGS. 1 and 2, the cell string 340 can include a plurality of memory cells connected between at least one transistor connected to the drain select line DSL and at least one transistor connected to the source select line SSL. To read data stored in a specific memory cell among the plurality of memory cells, a read voltage VREAD may be applied to the specific memory cell storing data, and a pass voltage VPASS may be applied to other memory cells. As various voltages are applied to the cell string 340, a current path including the bit line BL0 can be formed depending on whether data corresponding to the read voltage VREAD is stored in the specific memory cell, so that a current I_{CELL} can flow through the current path including the bit line BL0. Based on an amount of current I_{CELL} flowing through the bit line BL0, the page buffer 322 may read data stored in the specific memory cell to which the read voltage VREAD is applied, and temporarily store read data therein.

The bit line BL0 and the page buffer 322 are coupled to each other through a sensing output node SO. The bit line BL0 and the sensing output node SO could be coupled or decoupled by a bit line select signal SELBL and a decouple signal V_{DECOUPLE}, which are input to gates of transistors working as a switch.

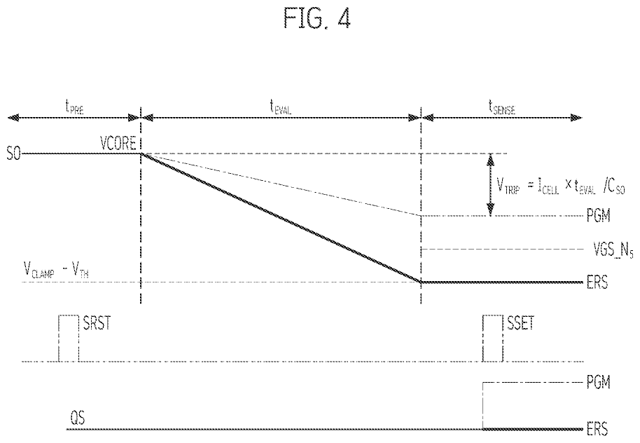

A potential or voltage level of the sensing output node SO may be determined based on either data stored in and output from a memory cell included in the cell string 340 or by a pre-charge signal PRECHSO_N and a clamp signal V_{CLAMP}. The precharge signal PRECHSO_N can be used for precharging the sensing output node SO with a predetermined voltage (e.g., a core voltage VCORE, see FIG. 4), and the clamp signal V_{CLAMP} can be used to apply a predetermined voltage to the sensing output node SO at a predetermined timing point for reducing a noise and increasing a sensing margin. According to an embodiment, the voltage levels of the pre-charge signal PRECHSO_N and the clamp signal V_{CLAMP} may be preset to offset a threshold voltage Vth of the transistor so that the core voltage VCORE could be applied to the sensing output node SO.

Referring to FIG. 4, a read operation or a verify operation may roughly include three operation sections. A first section is a bit line pre-charge section t_{PRE} in which a level of a bit line rises above a specific level that can be sensed. A second section is a bit line evaluation section t_{EVAL} in which a level of the bit line is maintained or decreased according to a current flowing through the cell string. A third section is a bit line sensing section t_{SENSE} for sensing how much the level of the bit line drops according to the current flowing through the cell string to determine whether a corresponding memory cell is programmed.

If the memory cell to which the read voltage VREAD is applied is programmed, that is, if a threshold voltage of the corresponding cell is greater than a verification voltage, the corresponding cell would be not turned on, so that a current path is not formed in the cell string including the corresponding cell and the voltage levels of the line BL0 and the sensing output node SO may be maintained at a high level (e.g., VCORE). If the corresponding cell is not programmed, that is, if the threshold voltage of the corresponding cell is less than the verification voltage, the corresponding cell would be turned on, so that a current path is formed in the cell string including the corresponding cell. In this case, voltage levels of the bit line BL0 and the sensing output node SO, which have been precharged to the high level, could be dropped to a lower level. As described above, because the levels of the bit line BL0 and the sensing output node SO become differently varied depending on whether the memory cell to which the read voltage VREAD is applied is programmed, data stored in the memory cell can be sensed and stored in the page buffer 322. A read operation will be described later with reference to FIG. 4.

FIG. 3 illustrates a first example of the page buffer according to an embodiment of the present disclosure.

Referring to FIG. 3, the page buffer 322 can include a latch implemented with cross-coupled inverters. The cross-coupled inverters can include two nodes QS, QS_N temporarily storing opposite values, a plurality of PMOS transistors, e.g., two PMOS transistors P₁, P₂, and a plurality of NMOS transistors, e.g., two NMOS transistors N₁, N₂.

The page buffer 322 can further include a fifth NMOS transistor N₅ connected to the sensing output node SO, a fourth NMOS transistor N₄ controlled by a sensing set signal SSET, and a third NMOS transistor N₃ controlled by a sensing reset signal SRST.

The fifth NMOS transistor N₅ may be turned on or off in response to a voltage level of the sensing output node SO. In the precharge section t_{PRE}, the voltage level of the sensing output node SO may be maintained at the core voltage VCORE in response to the precharge signal PRECHSO_N. When the voltage level of the sensing output node SO is maintained at the core voltage VCORE, the fifth NMOS transistor N₅ could be turned on.

When the sensing set signal SSET is activated, the fourth NMOS transistor N₄ may be turned on. Accordingly, the second node QS_N can be coupled to a ground voltage node for the ground voltage. The first node QS has a value opposite to that of the second node QS_N, that is, the first node QS may be coupled to a power voltage node for a power voltage, e.g., a core voltage node for the core voltage VCORE.

When the sense reset signal SRST is activated, the third NMOS transistor N₃ may be turned on. Accordingly, the first node QS is coupled to the ground voltage node. The second node QS_N having a value opposite to that of the first node QS could be coupled to the core voltage node VCORE.

FIG. 4 illustrates an operation of the page buffer according to an embodiment of the present disclosure.

Referring to FIG. 4, in the precharge section t_{PRE}, the sensing output node SO can be adjusted and maintained at the core voltage VCORE. The sensing reset signal SRST is activated, so that the first node QS is coupled to the ground voltage node.

In the bit line evaluation section t_{EVAL}, the voltage level of the sensing output node SO may be changed by a current path formed according to whether data is stored in a specific memory cell to which the read voltage VREAD is applied. For example, in a case when data corresponding to the read voltage VREAD is not stored in the memory cell (ERS), the voltage level of the sensing output node SO may become lowered to a first level (V_{CLAMP}−V_{TH}). When data corresponding to the read voltage VREAD is stored in the memory cell (PGM), the voltage level of the sensing output node SO may be lowered to a second level (VCORE−V_{TRIP}). The first level (V_{CLAMP}−V_{TH}) is lower than the second level (VCORE−V_{TRIP}). Herein, the trip voltage V_{TRIP} is generated due to a resistance component included in the current path formed through the cell string 340, the bit line BL0, and the sensing output node SO. For example, the trip voltage V_{TRIP} can be proportional to the current I_{CELL} flowing through the current path and the bit line evaluation section t_{EVAL}. Further, the trip voltage V_{TRIP} can be inversely proportional to a capacitance C_{SO} of the sensing output node SO.

In one embodiment, the fifth NMOS transistor N₅ in FIG. 3 may be designed to be turned on or off by a preset voltage VGS_N₅. Herein, the fifth NMOS transistor N₅ can be turned off by the first level (V_{CLAMP}−V_{TH}) but can be turned on by the second level (VCORE−V_{TRIP}).

When the sense set signal SSET is activated in the bit line sensing section t_{SENSE}, the page buffer 322 can store data corresponding to the voltage level of the sensing output node SO. When data is stored in the memory cell (PGM) to which the read voltage VREAD is applied, the first node QS may be varied to a logical high level. When data is not stored in the memory cell (ERS) to which the read voltage VREAD is applied, the first node QS may be varied to a logical low level.

Referring to FIGS. 3 and 4, in the precharge section t_{PRE} before sensing data output from the cell string, the memory device 150 can maintain the first node QS in the page buffer 322 at the logical low level. When it is determined that data is stored in a specific memory cell to which the read voltage VREAD is applied in the bit line sensing section period t_{SENSE}, the first node QS can transition to the logical high level (QS flip). Conversely, when it is determined that no data is stored in the specific memory cell to which the read voltage VREAD is applied, the low level of the first node QS is maintained (QS non-flip).

According to an embodiment, in a process of recognizing data stored in a memory cell to which the read voltage VREAD is applied through the page buffer 322, it might be difficult to recognize the data based on a location of the memory cell to which the read voltage VREAD is applied. For example, when a memory cell to which the read voltage VREAD is applied is located at a boundary between a memory cell in which data is programmed and a memory cell in which data is erased (not programmed), an error can occur in a value stored in the first node QS in the page buffer 322 when the sense set signal SSET is activated. Particularly, a short current can occur between the core voltage VCORE and the ground voltage in the page buffer 322, so that a latch fighting phenomenon may occur. Here, the latch fighting phenomenon indicates that a voltage level of the sensing output node SO, which is an input node of the page buffer 322, may be varied or fluctuated. Due to the latch fighting phenomenon, a situation where the core voltage VCORE becomes lower or the ground voltage becomes higher might occur. To avoid this situation, a size of the cross-coupled inverters (i.e., latch) should be increased or a channel width of the fifth NMOS transistor N₅ should be increased. In these solutions, an integration degree of the memory device 150 may be deteriorated.

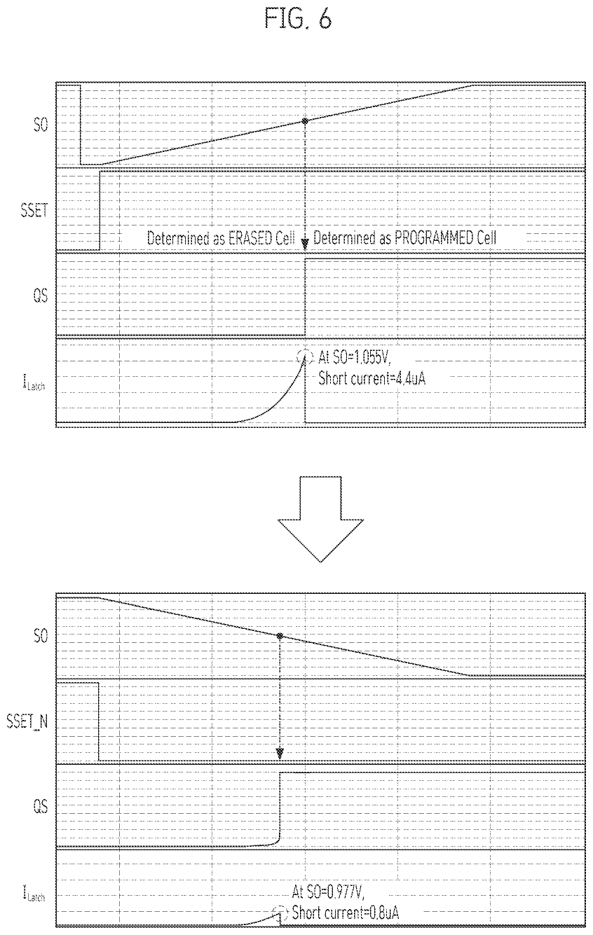

When a power supply (i.e., the core voltage VCORE) in the memory device 150 fluctuates, the page buffer 322 can differently determine a voltage level of the sensing output node SO even if a current I_{CELL} flowing in the current path formed through the cell string 340 is the same. That is, even though data stored in the memory cell to which the read voltage VREAD is applied is not changed, a logical value stored in the page buffer 322 would be different. This is because the second level (VCORE−V_{TRIP}), which is a voltage level of the sensing output node SO, may be different based on a level of the core voltage VCORE. When a latch current (I_{LATCH}, see FIG. 6) flowing in the cross-coupled inverters (i.e., latch) in the page buffer 322 is greater than a current flowing through the fifth NMOS transistor N₅, there might be an operational issue that a logical value stored in the second node QS_N is not changed. Thus, based on the case where data corresponding to the read voltage VREAD is stored in the memory cell (PGM) and the case where data corresponding to the read voltage VREAD is not stored in the memory cell (ERS), a phenomenon may occur in which values of the first node QS and the second node QS_N transition in a specific direction but do not transition in the opposite direction.

A sequential logic circuit such as a latch included in the page buffer 322 needs to store state information. Thus, the sequential logic circuit could be distinguished from a combinational logic circuit configured to only output a combination of current input values. For a property of state information storage, a latch is a component that has two stable states which could be used to store state information. As such, the latch has a simple purpose of storing logical value, i.e., storing a logical value (e.g., 1 or 0). However, the latch could be utilized in various static and dynamic implementations. One of the most frequently implemented forms is the use of positive feedback or regeneration.

Positive and negative feedback are two types of feedback systems used in electronic circuits. The main difference between positive and negative feedback is in the way a feedback signal affects an input signal. In a negative feedback scheme, the feedback signal is out of phase with the input signal. As the input signal increases, the feedback signal decreases, and vice versa. The negative feedback scheme can have an effect of reducing an operational gain and improving operational stability. Also, the negative feedback scheme can be used to reduce distortion and noise and improve operational linearity.

A positive feedback scheme can accelerate a signal conversion/transition speed. In the positive feedback scheme, an output signal is fed back to an input node in a manner that enhances the input signal, which in turn may proceed in a manner that enhances the output signal. This mechanism could induce a “regeneration” or “amplification” effect that can increase a gain on the circuit and speed up the change of the signal.

Issues caused by misalignment (e.g., incomplete manufacturing technology or design asymmetry) in the CMOS latch structure in the page buffer 322 raises the need to adjust a strength of positive feedback during an operation of the latch.

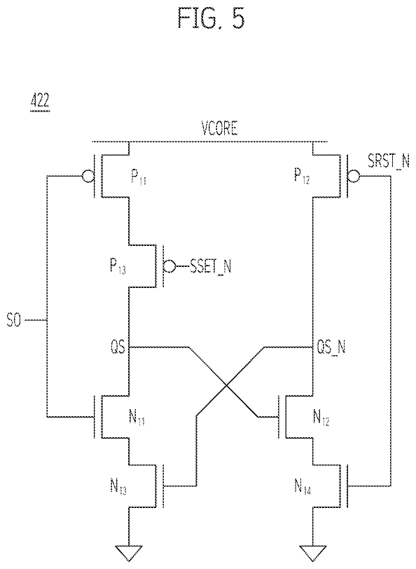

FIG. 5 illustrates a second example of the page buffer according to an embodiment of the present disclosure.

Referring to FIG. 5, the page buffer 422 can detect the voltage level of the sensing output node SO through a plurality of transistors P₁₁ and N₁₁, so that sensitivity regarding the voltage level of the sensing output node SO could be improved. In addition, the page buffer 422 can include a latch structure including cross-coupled NMOS transistors N₁₂, N₁₃ rather than a latch structure including cross-coupled inverters, so that an amount of latch current I_{LATCH} in the page buffer 422 can be reduced.

Referring to FIGS. 3 and 4, a preset voltage VGS_N₅ for sensing data is determined by one transistor (i.e., the fifth NMOS transistor N₅). When the power supply (i.e., the core voltage VCORE or the ground voltage) in the memory device 150 is fluctuated, operational stability could be degraded. On the other hand, referring to FIGS. 4 and 5, when the voltage level of the sensing output node SO is the second level (VCORE−V_{TRIP}), a level of a reference voltage used for detecting the voltage level of the sensing output node SO could be determined by the plurality of transistors P₁₁, N₁₁, so that operational stability could be improved even though the power supply (i.e., core voltage VCORE or the ground voltage) in the memory device 150 is fluctuated.

Referring to FIG. 5, the page buffer 422 can include a first PMOS transistor P₁₁ and a second PMOS transistor P₁₂ coupled to the core voltage node VCORE. The first PMOS transistor P₁₁ and the second PMOS transistor P₁₂ might not be cross-connected to each other. The sensing output node SO can be connected to a gate of the first PMOS transistor P₁₁, and a sensing reset inversion signal SRST_N can be applied to a gate of the second PMOS transistor P₁₂.

A third PMOS transistor P₁₃ can be arranged or disposed between the first PMOS transistor P₁₁ and the first node QS. A sense set inversion signal SSET_N can be applied to a gate of the third PMOS transistor P₁₃. No additional transistor may be disposed between the second PMOS transistor Piz and the second node QS_N.

The first node QS and the second node QS_N are individually coupled to a third NMOS transistor N₁₃ and a second NMOS transistor N₁₂ which constitute cross-connected NMOS transistors.

A first NMOS transistor N₁₁ having a gate coupled to the sensing output node SO may be disposed or arranged between the first node QS and the third NMOS transistor N₁₃.

The third NMOS transistor N₁₃ can be coupled to the ground voltage node. A fourth NMOS transistor N₁₄ may be disposed between the second NMOS transistor N₁₂ and the ground voltage node.

In the precharge section t_{PRE} before sensing data, the memory device 150 can maintain the first node QS in the page buffer 422 at the logical high level. When it is determined that data corresponding to a read voltage VREAD is stored in a specific memory cell in the bit line sensing section t_{SENSE}, the first node QS could be maintained at the logical high level (QS non-flip). Conversely, when it is determined that the data corresponding to the read voltage VREAD is not stored in the specific memory cell, the first node QS could transition to the logical low level (QS flip). In the two different page buffers 322, 422 described with reference to FIGS. 3 and 5, transition of the first node QS according to data corresponding to the read voltage VREAD could be differently achieved.

FIG. 6 illustrates operational comparison between the page buffers shown in FIGS. 3 and 5.

Referring to FIG. 6, an upper waveform diagram shows an operation of the page buffer 322 of FIG. 3, and a lower waveform diagram shows an operation of the page buffer 422 of FIG. 5. The latch currents I_{LATCH} when the first node QS in the page buffers 322, 422 transitions from a logical low level to a logical high level are described as an example. Here, the latch currents I_{LATCH} could include a short current generated during the transition of the first node QS.

As described above, transitions of the first node QS in the two different page buffers 322, 422 from a logical low level to a logical high level occur in different conditions opposite to each other. Therefore, in order to measure an amount of the latch current I_{LATCH} generated during a transition process, the voltage level of the sensing output node SO could be adjusted or changed in opposite directions (i.e., low to high, high to low) to measure the latch current I_{LATCH}.

According to an embodiment, the power supply (e.g., the core voltage VCORE or the ground voltage) may vary, and a reference voltage for determining data transition may also vary. Also, according to an embodiment, a magnitude of the trip voltage V_{TRIP} may also vary.

Referring to the upper waveform diagram of FIG. 6, when the core voltage VCORE of the page buffer 322 is 1.9V and the voltage of the sensing output node SO is 1.055V, the first node QS has transitioned. A short current generated when the first node QS transitions is about 4.4 μA.

Referring to the lower waveform diagram of FIG. 6, when the core voltage VCORE of the page buffer 422 is 1.9V and the voltage of the sensing output node SO is 0.977V, the first node QS has transitioned. A short current generated when the first node QS transitions is about 0.8 μA.

Comparing the waveform diagrams shown in FIG. 6, a difference in short currents generated when the first nodes QS of the page buffers 322, 422 transitions is five times or more. These short currents cause a difference in power consumption of the page buffers 322, 422. When the short current is large, power applied to the page buffers 322 and 422 (i.e., the core voltage VCORE or the ground voltage) could become unstable. Therefore, the page buffer 422 in FIG. 5 can have a latch current I_{LATCH} reduced by about ⅕ times, as compared to the page buffer 322 in FIG. 3, so that operational stability could also be improved.

In addition, the page buffer 422 in FIG. 5 can have an advantage. In the page buffer 422, the effect of the core voltage VCORE on the reference voltage for determining data corresponding to the read voltage VREAD can be reduced by about 40%, as compared to the page buffer 322 in FIG. 3.

Further, as compared to the page buffer 322 of FIG. 3, the page buffer 422 of FIG. 5 does not need to include a transistor having a long channel, thereby reducing a size of the page buffer 422. The integration degree of the memory device 150 could be improved.

As described above, a memory device according to an embodiment of the present invention can reduce an amount of current consumed during a data input/output operation, and thus can have improved performance in a low-power operating environment.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, generators and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, generators and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

While the present teachings have been illustrated and described with respect to the specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A memory device, comprising:
a cell string comprising a plurality of memory cells; and
a page buffer coupled to the cell string, the page buffer comprising a latch with cross-coupled transistors,
wherein data transferred from the cell string to the page buffer is input to gates of plural transistors included in the page buffer.

2. The memory device according to claim 1, wherein the plural transistors comprise:
a first node of the cross-coupled transistors;
a first PMOS transistor coupled to a power voltage node; and
a first NMOS transistor coupled to the first node.

3. The memory device according to claim 2, wherein the cross-coupled transistors comprise:
a second NMOS transistor having a gate coupled to the first node; and
a third NMOS transistor having a gate coupled to a second node temporarily storing a second value which is inverted from a first value temporarily stored in the first node.

4. The memory device according to claim 3, wherein the first NMOS transistor is arranged between the first node and the third NMOS transistor.

5. The memory device according to claim 2, wherein the page buffer further comprises a third PMOS transistor arranged between the first node and the first PMOS transistor, and
wherein an inverted signal of a sense set signal is input to a gate of the third PMOS transistor.

6. The memory device according to claim 1, wherein the page buffer further comprises a second PMOS transistor coupled to a power voltage node and a fourth NMOS transistor coupled to a ground voltage node, and
wherein an inverted signal of a sense reset signal is input to gates of the second PMOS transistor and the fourth NMOS transistor.

7. The memory device according to claim 4, wherein the page buffer comprises the first node having a logical high level during a precharge section, and
wherein the first node is configured to have the logical high level when data is transferred from the cell string and make a transition from the logical high level to a logical low level when no data is transferred from the cell string.

8. The memory device according to claim 1, wherein each of the memory cells is configured to store multi-bit data, and
wherein the data transferred from the cell string includes 1-bit data which is recognized by a read voltage among the multi-bit data when the read voltage is applied to at least one of the memory cells.

9. A memory device, comprising:
a cell string comprising plural memory cells;
a page buffer coupled to the cell string, the page buffer comprising a latch with cross-coupled transistors;
voltage generation circuitry configured to generate a read voltage and a pass voltage; and
control circuitry configured to generate a control signal to be input to the page buffer and the voltage generation circuitry.

10. The memory device according to claim 9, wherein data transferred from the cell string to the page buffer is input to gates of plural transistors included in the page buffer.

11. The memory device according to claim 10, wherein the plural transistors comprise:
a first node of the cross-coupled transistors;
a first PMOS transistor coupled to a power voltage node; and
a first NMOS transistor coupled to the first node.

12. The memory device according to claim 11, wherein the cross-coupled transistors further comprise:
a second NMOS transistor having a gate coupled to the first node; and
a third NMOS transistor having a gate coupled to a second node temporarily storing a second value which is inverted from a first value temporarily stored in the first node.

13. The memory device according to claim 12, wherein the first NMOS transistor is arranged between the first node and the third NMOS transistor.

14. The memory device according to claim 11, wherein the page buffer further comprises a third PMOS transistor arranged between the first node and the first PMOS transistor, and
wherein an inverted signal of a sense set signal is input to a gate of the third PMOS transistor.

15. The memory device according to claim 9, wherein the page buffer further comprises a second PMOS transistor coupled to a power voltage node and a fourth NMOS transistor coupled to a ground voltage node, and
wherein an inverted signal of a sense reset signal is input to gates of the second PMOS transistor and the fourth NMOS transistor.

16. The memory device according to claim 9, wherein the page buffer comprises the first node having a logical high level during a precharge section, and
wherein the first node is configured to have the logical high level when data is transferred from the cell string and make a transition from the logical high level to a logical low level when no data is transferred from the cell string.

17. The memory device according to claim 9, wherein each of the memory cells is configured to store multi-bit data, and
wherein the data transferred from the cell string includes 1-bit data which is recognized by a read voltage among the multi-bit data when the read voltage is applied to at least one of the memory cells.

18. The memory device according to claim 9, wherein the page buffer and at least one another page buffer are coupled to the cell string, and a number of page buffers coupled to the cell string is equal to or greater than a number of bits of data stored in each memory cell.

19. The memory device according to claim 9, wherein the cell string and the page buffer is coupled to each other through a bit line and a sensing output node, and
wherein the memory device further comprises:
precharge circuitry configured to precharge the bit line and the sensing output node; and
at least one switch configured to control connection between the bit line and the sensing output node.

20. The memory device according to claim 19, wherein the at least one switch is controlled by a signal output from the control circuitry.
